(19) United States
(12) Patent Application Publication
(10) Pub. No.: US 2024/0095426 A1
(43) Pub. Date: Mar. 21, 2024

(54) TREE-BASED LEARNING METHODS THROUGH TUBING CEMENT SHEATH QUALITY ASSESSMENT

(71) Applicant: Halliburton Energy Services, Inc., Houston, TX (US)

(72) Inventors: Brenno Caetano Troca CABELLA, Rio de Janeiro (BR); Otto Fanini, Houston, TX (US); Xiang Wu, Singapore (SG)

(73) Assignee: Halliburton Energy Services, Inc., Houston, TX (US)

(21) Appl. No.: 17/945,823

(22) Filed: Sep. 15, 2022

(51) Int. Cl. G06F 30/27; G01V 99/00

(52) U.S. Cl. CPC G06F 30/27; G01V 99/005

(57) ABSTRACT

Aspects of the subject technology relate to systems and methods for identifying the quality of cement bonding of an exterior surface of a wellbore casing to an Earth formation. Methods of the present disclosure may allow for bond indexes to be identified in real-time as a cementing operation is performed even when tools that perform the cementing operation generate acoustic noise that interfere with measurements used to evaluate cement bonding quality. These methods may include transmitting acoustic signals, receiving acoustic signals, filtering the received acoustic signals, identifying magnitude and attenuation values to associate with the received acoustic signals, and comparing trends in the magnitudes with the identified attenuation values. These methods may also include correcting attenuation values associated with measured data based on a set of correction rules such that bond indexes can be identified. Such correction rules may be associated with data generated by a computer model.

### TECHNICAL FIELD

The present disclosure is generally directed to the processing of data associated with a wellbore. More specifically, the present disclosure is directed to characterizing the quality of a wellbore.

### BACKGROUND

Cementing an oil or gas well includes pumping cement into an annulus between the casing and a rock formation or between two casings after a well is drilled. This is a key step of well completion to keep formation integrity. For cementing quality control, it is necessary to quantitatively measure the bonding condition at the interfaces between casing, cement, and a rock formation. Cement bond logging (CBL) plays an important role in determining well integrity and CBL is a way to ensure that a wellbore has acceptable levels of zonal isolation. Thus, CBL is an important topic in acoustic well logging.

### BRIEF DESCRIPTION OF THE DRAWINGS

In order to describe the manner in which the features and advantages of this disclosure can be obtained, a more particular description is provided with reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIG. 1A is a schematic diagram of an example logging while drilling wellbore operating environment, in accordance with various aspects of the subject technology.

FIG. 1B is a schematic diagram of an example downhole environment having tubulars, in accordance with various aspects of the subject technology.

FIG. 2 illustrates a wellbore that is monitored in real-time as a wellbore cementing operation is performed, in accordance with various aspects of the subject technology.

FIG. 3 illustrates a wellbore casing that includes a rotating acoustic transmitter that may be used to collect data regarding the quality of cement that binds the wellbore casing to an Earth formation, in accordance with various aspects of the subject technology.

FIG. 4 illustrates a mapping that may be performed from data collected from the acoustic receivers that may be included in an acoustic assembly, in accordance with various aspects of the subject technology.

FIG. 5 illustrates a tree that includes preceding nodes and following nodes, where each of the preceding nodes is associated with characteristics and Boolean operations that may be used to identify the structure of a computer model, in accordance with various aspects of the subject technology.

FIG. 6 illustrates a series of actions that may be performed when a computer model is created, trained, and applied to generate wellbore bond maps, in accordance with various aspects of the subject technology.

FIG. 7 illustrates a series of actions that may be performed by a processor when a computer model is trained, in accordance with various aspects of the subject technology.

FIG. 8 illustrates a set of actions that may be performed when a bond log generated based on using the computer model is validated, in accordance with various aspects of the subject technology.

FIG. 9 illustrates an example set of data that shows areas of a wellbore cross-section that include areas fully filled with cement and areas where a channel appears to exist in the wellbore, in accordance with various aspects of the subject technology.

FIG. 10 illustrates an example computing device architecture which can be employed to perform various steps, methods, and techniques disclosed herein.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

Additional features and advantages of the disclosure will be set forth in the description which follows, and in part will be obvious from the description, or can be learned by practice of the principles disclosed herein. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Aspects of the subject technology relate to systems and methods for identifying the quality of cement bonding of an exterior surface of a wellbore casing to an Earth formation. Methods of the present disclosure may include transmitting acoustic signals, receiving acoustic signals, filtering the received acoustic signals, identifying magnitude and attenuation values to associate with the received acoustic signals, and comparing trends in the magnitudes with the identified attenuation values. These methods may also include generating a computer model that may use sets of Boolean decision trees and may include training the computer model using modified sets information or limits. Once a computer model is trained the computer model may be used to generate bond logs of a reference wellbore or of other wellbores. Bond logs generated using the computer model may be compared to see if they agree with bond logs generated using other techniques.

Cementing an oil or gas well includes pumping cement into an annulus between the casing and a rock formation or between two casings after a well is drilled. This is a key step of well completion to keep formation integrity. For cementing quality control, it is necessary to quantitatively measure the bonding condition at the interfaces between casing, cement, and a rock formation. Cement bond logging (CBL) plays an important role in determining well integrity and CBL is a way to ensure that a wellbore has acceptable levels of zonal isolation. Thus, CBL is an important topic in acoustic well logging. A process of generating cement bond logs while cement is pumped into the annulus of the wellbore is referred to herein as logging-while-drilling (LWD). Creating cement bond logs during a cementing operation would provide oil and gas companies with benefits that include cost reduction, reduction in tool decentering effects, and mitigating tool conveyance issues.

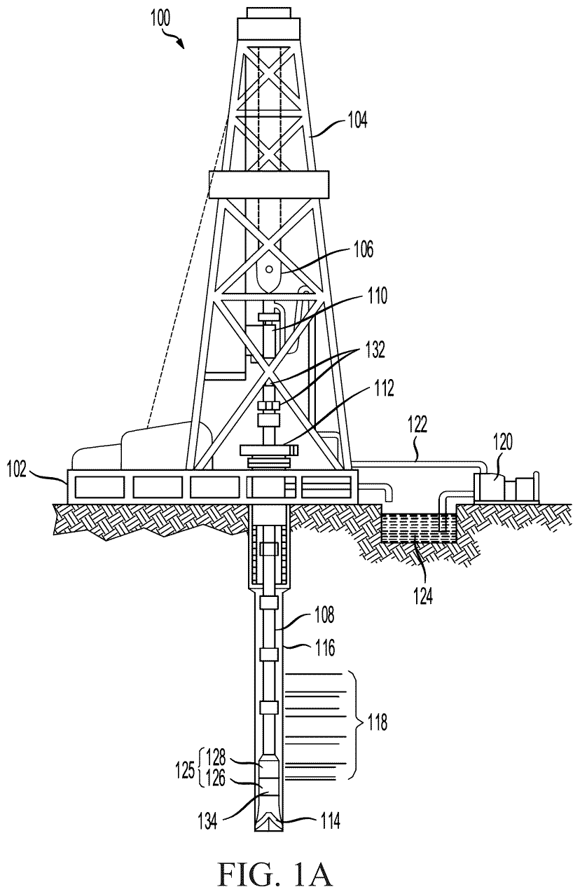

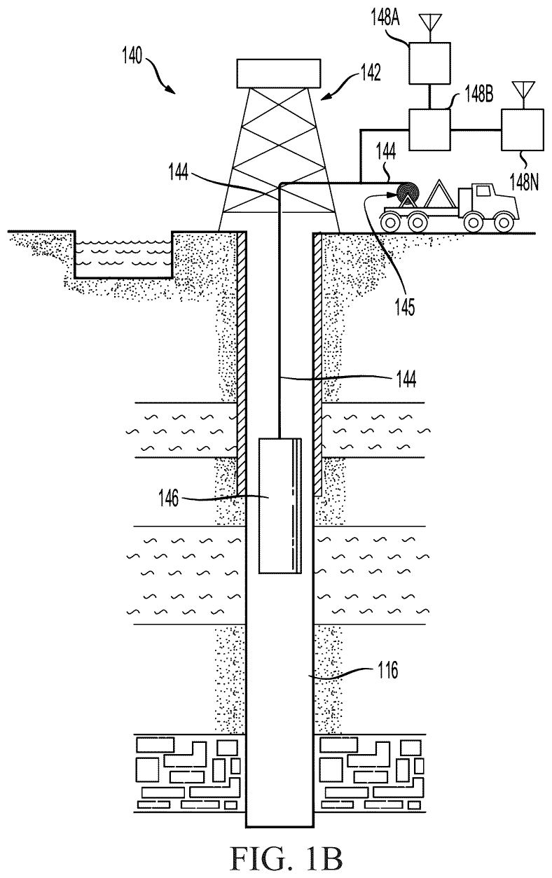

Turning now to FIG. 1A, a drilling arrangement is shown that exemplifies a Logging While Drilling (commonly abbreviated as LWD) configuration in a wellbore drilling scenario 100. Logging-While-Drilling typically incorporates sensors that acquire formation data. Specifically, the drilling arrangement shown in FIG. 1A can be used to gather formation data through an electromagnetic imager tool as part of logging the wellbore using the electromagnetic imager tool. The drilling arrangement of FIG. 1A also exemplifies what is referred to as Measurement While Drilling (commonly abbreviated as MWD) which utilizes sensors to acquire data from which the wellbore's path and position in three-dimensional space can be determined. FIG. 1A shows a drilling platform 102 equipped with a derrick 104 that supports a hoist 106 for raising and lowering a drill string 108. The hoist 106 suspends a top drive 110 suitable for rotating and lowering the drill string 108 through a well head 112. A drill bit 114 can be connected to the lower end of the drill string 108. As the drill bit 114 rotates, it creates a wellbore 116 that passes through various subterranean formations 118. A pump 120 circulates drilling fluid through a supply pipe 122 to top drive 110, down through the interior of drill string 108 and out orifices in drill bit 114 into the wellbore. The drilling fluid returns to the surface via the annulus around drill string 108, and into a retention pit 124. The drilling fluid transports cuttings from the wellbore 116 into the retention pit 124 and the drilling fluid's presence in the annulus aids in maintaining the integrity of the wellbore 116. Various materials can be used for drilling fluid, including oil-based fluids and water-based fluids.

Logging tools 126 can be integrated into the bottom-hole assembly 125 near the drill bit 114. As both drill bit 114 extends into the wellbore 116 through the formations 118 and as the drill string 108 is pulled out of the wellbore 116, logging tools 126 collect measurements relating to various formation properties as well as the orientation of the tool and various other drilling conditions. The logging tool 126 can be applicable tools for collecting measurements in a drilling scenario, such as the electromagnetic imager tools described herein. Each of the logging tools 126 may include one or more tool components spaced apart from each other and communicatively coupled by one or more wires and/or other communication arrangement. The logging tools 126 may also include one or more computing devices communicatively coupled with one or more of the tool components. The one or more computing devices may be configured to control or monitor a performance of the tool, process logging data, and/or carry out one or more aspects of the methods and processes of the present disclosure.

The bottom-hole assembly 125 may also include a telemetry sub 128 to transfer measurement data to a surface receiver 132 and to receive commands from the surface. In at least some cases, the telemetry sub 128 communicates with a surface receiver 132 by wireless signal transmission (e.g., using mud pulse telemetry, EM telemetry, or acoustic telemetry). In other cases, one or more of the logging tools 126 may communicate with a surface receiver 132 by a wire, such as wired drill pipe. In some instances, the telemetry sub 128 does not communicate with the surface, but rather stores logging data for later retrieval at the surface when the logging assembly is recovered. In at least some cases, one or more of the logging tools 126 may receive electrical power from a wire that extends to the surface, including wires extending through a wired drill pipe. In other cases, power is provided from one or more batteries or via power generated downhole.

Collar 134 is a frequent component of a drill string 108 and generally resembles a very thick-walled cylindrical pipe, typically with threaded ends and a hollow core for the conveyance of drilling fluid. Multiple collars 134 can be included in the drill string 108 and are constructed and intended to be heavy to apply weight on the drill bit 114 to assist the drilling process. Because of the thickness of the collar's wall, pocket-type cutouts or other type recesses can be provided into the collar's wall without negatively impacting the integrity (strength, rigidity and the like) of the collar as a component of the drill string 108.

Referring to FIG. 1B, an example system 140 is depicted for conducting downhole measurements after at least a portion of a wellbore has been drilled and the drill string removed from the well. An electromagnetic imager tool can be operated in the example system 140 shown in FIG. 1B to log the wellbore. A downhole tool is shown having a tool body 146 in order to carry out logging and/or other operations. For example, instead of using the drill string 108 of FIG. 1A to lower the downhole tool, which can contain sensors and/or other instrumentation for detecting and logging nearby characteristics and conditions of the wellbore 116 and surrounding formations, a wireline conveyance 144 can be used. The tool body 146 can be lowered into the wellbore 116 by wireline conveyance 144. The wireline conveyance 144 can be anchored in the drill rig 142 or by a portable means such as a truck 145. The wireline conveyance 144 can include one or more wires, slicklines, cables, and/or the like, as well as tubular conveyances such as coiled tubing, joint tubing, or other tubulars. The downhole tool can include an applicable tool for collecting measurements in a drilling scenario, such as the electromagnetic imager tools described herein.

The illustrated wireline conveyance 144 provides power and support for the tool, as well as enabling communication between data processors 148A-N on the surface. In some examples, the wireline conveyance 144 can include electrical and/or fiber optic cabling for carrying out communications. The wireline conveyance 144 is sufficiently strong and flexible to tether the tool body 146 through the wellbore 116, while also permitting communication through the wireline conveyance 144 to one or more of the processors 148A-N, which can include local and/or remote processors. The processors 148A-N can be integrated as part of an applicable computing system, such as the computing device architectures described herein. Moreover, power can be supplied via the wireline conveyance 144 to meet power requirements of the tool. For slickline or coiled tubing configurations, power can be supplied downhole with a battery or via a downhole generator.

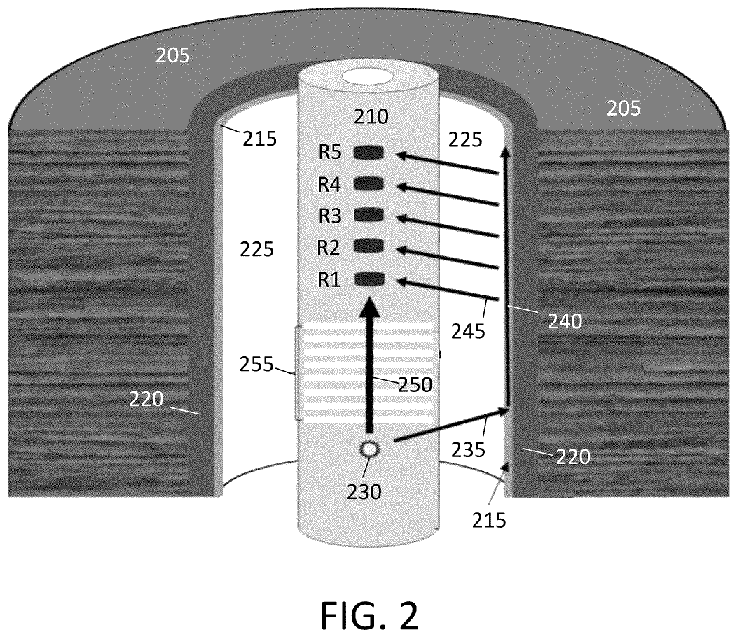

FIG. 2 illustrates a wellbore that is monitored in real-time as a wellbore cementing operation is performed. FIG. 2 includes a hole 225 in formation 205 that includes casing 215 into which tool 210 has been inserted during a wellbore cementing operation. Casing 215 may be made using threaded steel pipes that are joined together as the wellbore is made. As tool 210 moves down the wellbore, cement may be pumped to fill spaces between an outside surface of casing 215 and formation 205. In certain instances, area 225 located between tool 210 and internal surfaces of casing 215 may be initially filled with a drilling mud. Cement may then be pumped to fill gaps between then casing 215 and the formation 205 and the pumping of the cement may displace this mud. At this time acoustic waves 235 may be transmitted from transmitter 230 toward casing 215. These transmitted acoustic waves 235 impact casing 215 and travel along casing 215 upward as indicated by arrow 240 (i.e., acoustic waves 240). After traveling up casing 215, energy from acoustic waves 245 travels back toward tool 210 as acoustic waves 245 to receivers R1-R5 (R1, R2, R3, R4, and R5). As the acoustic waves 245 are received at receivers R1-R5, characteristics associated with those received waves may be used to identify whether and to what extent cement has filled areas 220 between an outer surface of casing 215 and formation 205. Generally, areas on the outside of casing 215 that are bonded to the formation 205 with cement will be associated with greater levels of acoustic attenuation than areas where the outside of casing 215 are not bonded to the formation 205. This is because acoustic attenuation values tend to increase with the quality of cement bonds. Because of this, analysis may be performed on received acoustic energy from acoustic waves 245 to identify the quality of a wellbore cementing process.

Energy from vibrations associated with the pumping of the cement are illustrated by arrow 250. Such vibrations may be referred to as tool waves 250 that have the potential to interfere with accurately measuring acoustic attenuation values. Tool 210 includes isolator 255 that is designed to dampen tool waves 250 before those waves reach receivers R1-R5 in an effort to mitigate tool waves 250 from interfering with real-time measurements of casing wave magnitudes and related determinations of acoustic attenuation. Since isolator 255 is not perfect, some of the energy from tool waves 250 is still received by receivers R1-R5. As mentioned above, energy from tool waves 250 received by receivers R1-R5 may interfere with measurements and acoustic attenuation value determinations. Furthermore, acoustic energy from any exterior source received by receivers R1-R5 may interfere with the process of determining the quality of wellbore bonds. Because of this, methods of the present disclosure may include making compensations to measured acoustic attenuation values when actual or real acoustic attenuation values are identified. The tool 210 of FIG. 2 is an example of one type of tool that may be used to collect wellbore data. In certain instances, such wellbore tools may have elements that rotate within tubing disposed inside of casing 215.

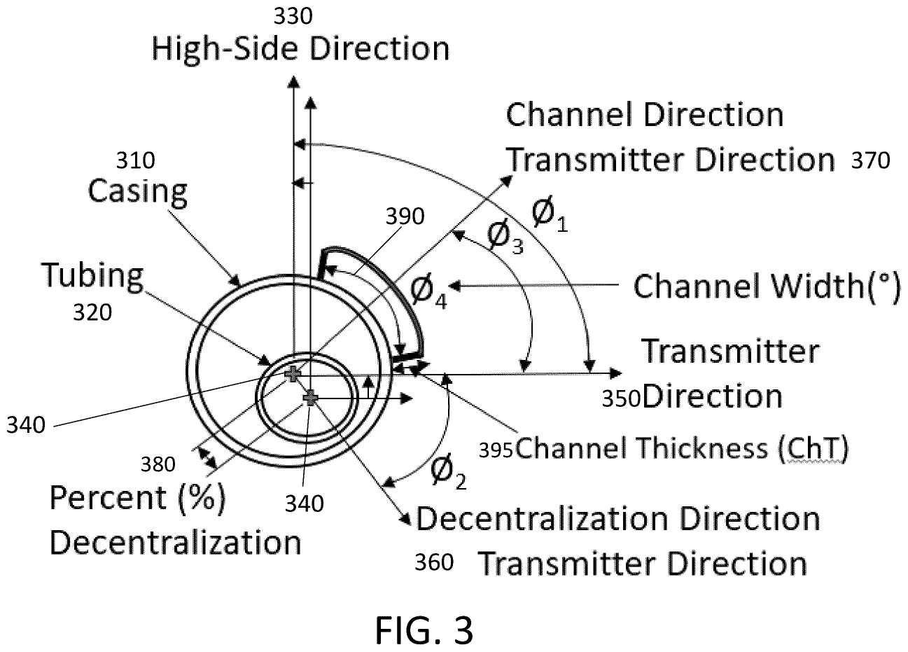

FIG. 3 illustrates a wellbore casing that includes a rotating acoustic transmitter that may be used to collect data regarding the quality of cement that binds the wellbore casing to an Earth formation. FIG. 3 includes tubing 320 that has been inserted into casing 310 of a wellbore. Item 330 corresponds to radial position of the wellbore casing that may be referred to as a high-side direction. This high-side direction 330 may be used as a reference radial position. Within the tubing is a rotating acoustic assembly that includes transmitter 340. Transmitter 340 is represented with a plus symbol +. Arrowed lines 350, 360, and 370 that show acoustic waves being transmitted from transmitter 340 in different directions as the acoustic assembly rotates. Text of FIG. 3 indicates that arrowed line 350 corresponds to a transmitter direction at a first radial position, that arrowed line 360 corresponds to a decentralized transmitter direction at a second radial position, and that arrowed line 370 corresponds to a radial direction where channel 390 is located in the wellbore. Channels in a wellbore may be areas where cement of the wellbore does not secure the casing to an Earth formation above a threshold level. These channels may be areas where wellbore cement is cracked, may be areas where voids exist in the cement, may be areas where water or brine is located next to wellbore cement, or may be areas where drilling mud mixes with cement. Such channels may include sub-millimeter gaps in the cement or larger cement voids.

As the acoustic assembly rotates, transmitter 340 may move side to side in tubing 320. This is indicated by the doubled arrowed line 380 and a measure of this side to side movement may be referred to as decentralization that may be expressed as a percentage of an inner diameter of tube 320. What this means is that the transmitter 340 may have an eccentric motion that can be assigned a decentralization value. As discussed in respect to FIG. 2, an acoustic assembly may include receivers that receive acoustic signals that have traveled along a wellbore casing after being transmitted from an acoustic transmitter. Data received by these receivers may be used to evaluate how well a casing has been cemented into a wellbore.

As discussed above, examples of channels in a wellbore include cracks, voids, or other anomalies that prevent cement from bonding to an Earth formation to a threshold level. Note that channel 390 spans an area of part of an outer surface of casing 310. FIG. 3 includes various angles ø1, ø2, ø3, and ø4. Angle ø1 is an angle between the reference high-side 330 radial position and the first radial position of the transmitter direction 350. Angle ø2 is an angle between the first radial position transmitter direction 350 and the second radial position decentralized transmitter direction 360. Angle ø3 is an angle between first radial position transmitter direction 350 and the radial position where channel 390 is located. Angle ø4 is an angle that corresponds to a width of channel 390. FIG. 3 also includes doubled arrowed line 395 that identifies a thickness of channel 390.

Various characteristics may be associated with the various parts of the wellbore and to channels that may exist after a cementing process has been performed. Characteristics associated with channel 390 may include the channel width angle ø4, a channel thickness, a channel height, and an Earth formation type parameter. Characteristics associated with tubing 320 may include a tubing outside diameter, a tubing inside diameter, a tubing thickness, a tubing eccentricity, and a tubing material parameter. Characteristics associated with the casing 310 may include a casing outer diameter, a casing inner diameter, a casing thickness, a casing eccentricity, and a casing material parameter. Values for many of these characteristics may vary along the length or depth of a wellbore and each of these different characteristics and related variances may affect the quality of measurements directed to evaluating the quality of wellbore cement.

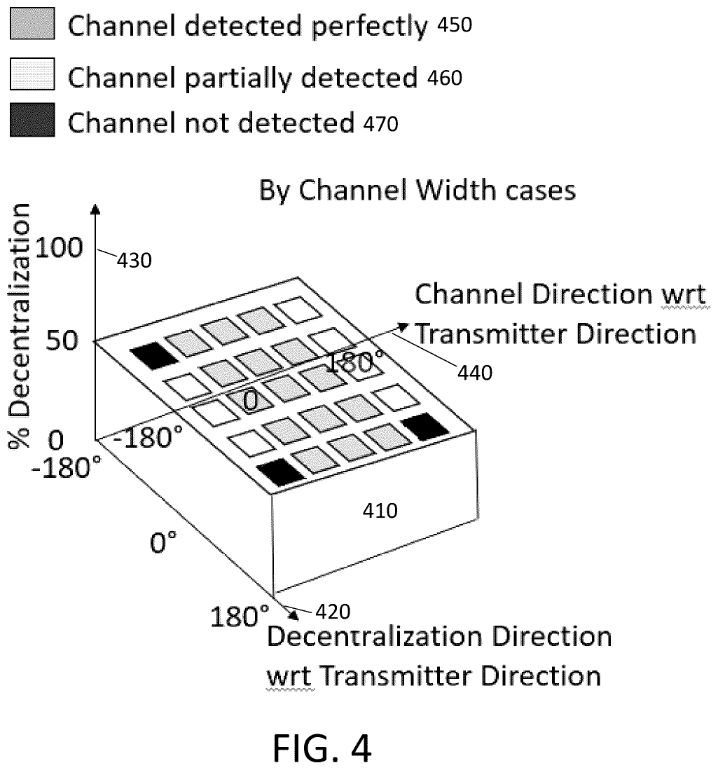

FIG. 4 illustrates a mapping that may be performed from data collected from the acoustic receivers that may be included in an acoustic assembly. FIG. 4 is a three-dimensional (3D) mapping 410 that includes axis 420 that corresponds to the decentralized transmitter direction 360 of FIG. 3, axis 430 that corresponds to the percent decentralization 380 of FIG. 3, and axis 440 that corresponds to the channel direction 370 of FIG. 3. Note that the scale of the decentralized transmitter direction axis 420 and the scale of the channel direction axis 440 vary from minus one hundred eight degrees to one hundred degrees. Note also that the scale of the percent decentralization axis 430 varies from zero percent to a value of 100 percent.

The 3D mapping 410 includes color coded indicators of dark gray (450) that corresponds to a perfect detection of a channel, a light gray/white (460) color that corresponds to a partially detected channel, and to a black (470) color that corresponds to the channel not being detected. This means that the 3D mapping 410 of FIG. 1 may be used to identify locations of the wellbore where channels are located. Note that areas in a center portion of the 3D mapping 410 are areas where a channel has been detected.

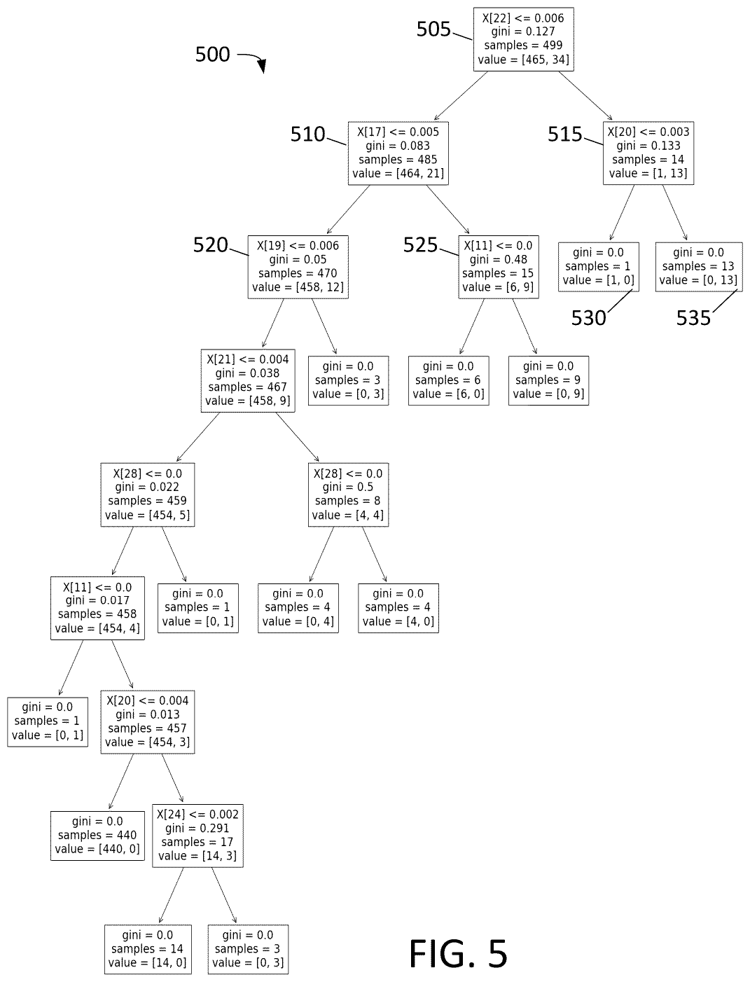

FIG. 5 illustrates a tree that includes preceding nodes and following nodes, where each of the preceding nodes is associated with characteristics and Boolean operations that may be used to identify the structure of a computer model. The tree 500 of FIG. 5 begins with preceding node 505 that is connected to follower nodes 510 and 515. Nodes 510 and 515 are also preceding nodes because they each are respectively connected to two different subsequent nodes: nodes 520 and 525 are both follower nodes of node 510, and nodes 530 and 535 are follower nodes of node 515. Since nodes 530 and 535 do not connect to additional follower nodes, nodes 530 and 535 may only be characterized as follower nodes.

Node 505 is associated with notations, numbers, or values of X[22] that is a notation identifies a frequency of 22 thousand Hertz (KHz) being less than or equal to a value of voltage or pressure. In certain instances, a voltage value of 0.006 volts may correspond to signal magnitude of a specific pressure, a Gini value of 0.127, a number of samples of 499, and other values [465, 34]. When a magnitude of a received acoustic signal of 22 KHz is less than or equal to 0.006 volts, the left branch attached to node 505 will be followed to node 510 and when the value of the received 22 KHz acoustic signal is greater than 0.006 volts, the right branch attached to node 505 will be followed to node 515. This means that the Boolean operation associated with node 505 is related to a measured magnitude of a received acoustic signal at 22 KHz. Values of acoustic samples evaluated by the Boolean operation of node 505 may have been identified from wellbore data that was collected using transmitters and receives discussed in respect to FIGS. 2-3. The Gini impurity value may be a metric that may be used to select a feature that best splits collected data into left and right branches. Here a purer split of data may be identified by a lower Gini value. Method of the present disclosure may also include a boosting procedure that may include generating sequences of trees where each new subsequent tree enhances an error associated a previous tree or tree branch.

The frequency values may be referred to as features. Hyperparameters for an ensemble tree-based method may include “leaning rate” and “n_estimators”. Here the learning rate may be a hyperparameter that controls how much weights to the computer model are adjusted from run to run of the computer model. The n estimator hyperparmeters may be a number of trees used in the computer model. Features may be related to the data we collect (e.g. frequency components of the input signals) and hyperparameters may be intrinsic part of the machine learning algorithm. The gini value in FIG. 5 is commonly referred to as Gini index or Gini impurity value that may vary between a value of zero and a value of one.

Tree 500 begins at node 505 with a total number of samples of 499, where node 510 is has a number of samples of 485 and node 515 has a number of samples of 14. Different Boolean operations may be performed from either of step 510 or 515. A Boolean operation associated with node 510 may evaluate whether a frequency associated with a 17 KHz signal (as indicated by the X[17] notation) has a value less than or equal to 0.005 volts. When ab sample of collected data is compared to the Boolean operation of node 510, a left branch connected to node 510 may be taken when the sample at 17 KHz has a value that is less than or equal to 0.005 volts. When this sample of collected data has a magnitude of greater than 0.005 volts, the right branch of node 510 may be taken.

A Boolean operation associated with node 510 identifies that the left branch should be taken with a sample has a magnitude of a 20 KHz signal (as indicated by the X[20] notation) is less than or equal to a value of 0.003 decibels and that a right branch of node 515 should be taken when the sample has a magnitude of the 20 KHz signal is greater than 0.003 decibels. Note that following node 530 is associated with only one sample of acoustic data and that node 535 is associated with thirteen samples of acoustic data.

The left branches of FIG. 5 may be associated with cemented positions of a wellbore and the right branches of FIG. 5 may be associated with locations of the wellbore that include a channel. Tree 500 may be associated with a model that is used to evaluate the quality of cement in a wellbore.

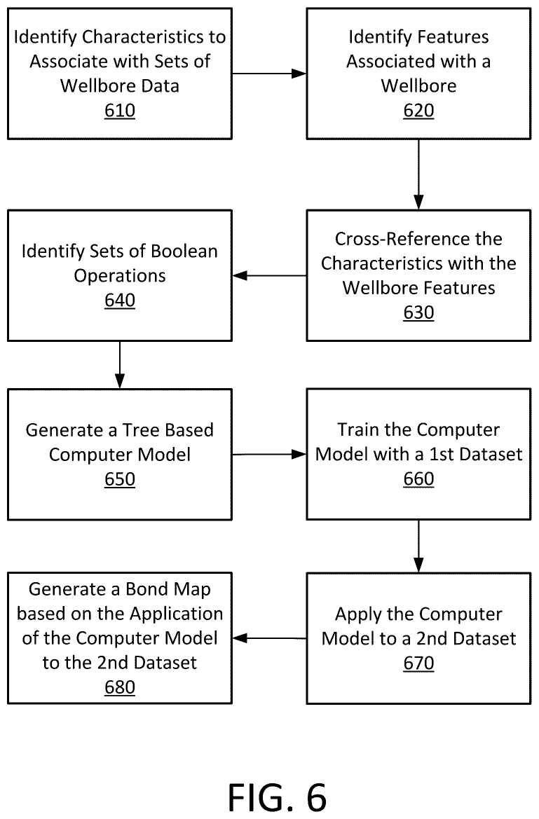

FIG. 6 illustrates a series of actions that may be performed when a computer model is created, trained, and applied to generate wellbore bond maps. FIG. 6 beings with step 610 where characteristics associated with sets of wellbore data may be identified. These characteristics may be associated with data of a physical nature, for example, a frequency, an attenuation associated with a transmitted acoustic wave, a magnitude of measured acoustic power, a measure or value of time, a space value, or a measure of density. Next, in step 620, features associated with wellbore may be identified. The wellbore features identified in step 620 may include one or more of a type of casing, a type of ground material, a type of cement, a casing thickness, a casing inner diameter, a casing out diameter, a casing thickness, a channel thickness, eccentricities (of the wellbore, a wellbore casing, or wellbore tubing), an angle associated with an acoustic transmitter, a type of tubing, a tubing thickness, and a decentralization value of a transmitter from a center point of the wellbore or a set of tubing that is located within the wellbore.

The characteristics discussed above may be or include a physical parameter or measurement values, where the wellbore features may relate to structural parameters or materials of a wellbore or wellbore components. A characteristic and feature may be closely related for example a feature of a casing may identify that the casing is comprised of medium carbon steel and characteristic of that corresponds to that feature is a density of medium carbon steel. While medium carbon steel may have a nominal density of 7.83 grams per cubic centimeter (grams/cubic-cm), actual values of this medium carbon steel may span a range of about 7.82 to 7.84 grams/cubic-cm. As such, characteristics of a casing or other materials may vary. An eccentricity of a wellbore casing thickness variations in a casing may mean that features of the wellbore casing may vary and such variations may correspond to variations in how much material of a given density is located at a cross-section of the casing.

It may be expected that man-made wellbore components will tend to have only small variations in related features or characteristics. It may also be expected that non-man-made components of the wellbore may be associated with large variations of features or characteristics. This is because, man-made materials have controlled tolerances, where formations in the Earth do not. Earth formations may include various different kinds of materials that change along the length of the wellbore. For example, when Earthen formations of a wellbore could include Basalt rock, Sandstone, and Granite. Each of these different types of rocks have different densities: Basalt has a density of about 3.011 grams/cubic-cm, Sandstone has a density of about 2.32 grams/cubic-cm, and Granite has a density of about 2.50 to 2.81 grams/cubic-cm. Similarly, densities of certain types of cement may also be associated with features and corresponding characteristics.

After step 620, the identified characteristics and associated wellbore features may be cross-referenced in step 630. This could include associating a feature of granite rock with densities of 2.5, 2.6, 2.7 and 2.8 grams/cubic-cm when sets of Boolean decision trees are generated. Sets of Boolean operations to associate with particular nodes of a computer model may be identified in step 640, and a computer model may be generated in step 650. This computer model may include many different decision trees that have different limit values or constraints. After step 650, the computer model may be trained using a first dataset in step 660. This first dataset may include data that was acquired from an actual wellbore. Multiple iterative runs of the computer model may be performed using variations in features, characteristics, limit values, or other constraints until the computer model is trained to a threshold level. While not illustrated in FIG. 6, data in a dataset may be prepared before evaluations are performed on that data. This may include filtering the data, merging datasets, eliminating outliers, filling gaps in the data, or deleting unnecessary entries.

It is possible that variations in features and/or characteristics could result in interpretations of wellbore data not comporting to expectations about the wellbore. For example, a computer model could estimate densities of specific materials when certain evaluations are performed and because of this a particular evaluation could yield to an erroneous result. In an instance when an attenuation of an acoustic wave is near a level that corresponds to a location where a wellbore channel exists (e.g. cracked cement or a cement void), variations associated with the features and characteristics used by the computer model may cause a decision tree to change from following a left branch of a Boolean decision tree to following a right branch of the Boolean decision tree. In respect to node 505 of FIG. 5, changes in values or parameters associated with certain features and characteristics may result in the node 505 being associated with either a threshold of 0.0060 decibels or 0.0062 decibels. When a dataset included a magnitude of 0.0060 decibels, a path associated with traversing the decision tree will change when the threshold changes from 0.0060 decibels to 0.0062 decibels. This means that a computer model could yield erroneous results. Because of this, computer models of the present disclosure may include many different Boolean decision trees that each may have slightly different feature or characteristic values. Determinations made by these different decision trees may count as votes that may incrementally affect a particular determination. Training of the computer model may include running multiple iterations of the computer model with slightly different constraints until the computer model converges to a solution by meeting a threshold level.

In an instance when votes of the computer model correspond to a 70% chance that a channel is not detected, a 25% chance that a channel is detected, and a 5% chance that a channel is perfectly detected. Variations in the constraints of the computer model (e.g. variations in features, characteristics, or determination levels) may be modified and the computer model may be run recursively until the votes meet a threshold level of a 90% chance that the channel is not detected.

After step 660, the trained computer model may be applied to a second dataset. This second dataset may include data that describes features of this second wellbore, characteristics of this second wellbore, and may include data sensed at the second wellbore by a wellbore tool. This wellbore sensed data may include magnitudes of transmitted energy, magnitudes of received energy, and/or attenuation values of energy that moves along a casing of the wellbore. The closer a set of features and characteristics of the first dataset and the second dataset correspond, the more likely the trained computer model will generate accurate results when generating a bond map of the second wellbore. The bond map may then be generated in step 680 of FIG. 6. This bond map may be provided to regulators that are responsible for overseeing the quality of a wellbore. Such regulators may authorize that a particular wellbore can be placed into service after reviewing the bond map.

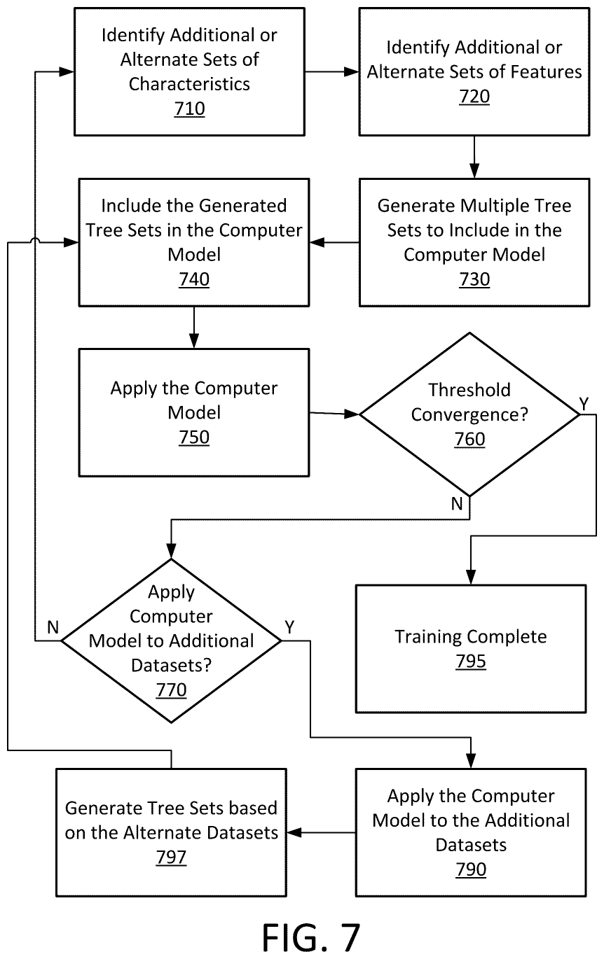

FIG. 7 illustrates a series of actions that may be performed by a processor when a computer model is trained. As discussed in respect to FIG. 6, an initial set of characteristics and features associated with a wellbore may have been identified when a computer model training session is initiated. After this initial set of characteristics and features have been identified, additional or alternate sets of characteristics may be identified in step 710 and additional or alternate sets of features may be identified in step 720. While not shown in FIG. 7, these alternate sets of characteristics and features may have been identified based on a number of votes or voting percentage not meeting a threshold level as discussed in respect to FIG. 6. Here again, these additional characteristics and features may result in

Multiple additional tree sets may then be generated in step 730 and those additional tree sets may be included in the computer model in step 740. These updated tree sets may include changes to Boolean operations. Again, as discussed in respect to FIG. 5, such changes in Boolean operations may include changing a value that is compared to magnitudes of a signal of a particular frequency. The updated computer model may than be applied to a dataset in step 750 and determination step 760 may identify whether the training of the computer model has reached a threshold convergence level. As discussed above, such a convergence level may require that 90% of votes made by the computer model reach a same conclusion. When determination step 760 identifies that the threshold convergence level has been met, program flow may move to step 795 where training of the computer model may be completed.

When determination step 760 identifies that the threshold convergence level has not been met, program flow may move to determination step 770 that may identify whether the computer model should be applied to additional datasets. When no, program flow may move back to step 710 where one more or additional or alternate sets of characteristics are identified. When determination step 770 identifies that the computer model should be applied to additional or other datasets, program flow may move to step 790 where the computer model is applied to those additional or other datasets. Additional tree sets may then be generated in step 797 after which program flow may move back to step 740 where those additional tree sets are included in the computer model.

The steps of FIG. 7 illustrate that a training process may be performed using one or many different datasets in combination with many different Boolean decision trees that may include slight variations in characteristics, features, limits, or comparison values. The steps of FIG. 7 may be performed iteratively until the threshold convergence level is met. In certain instances, method of the present disclosure may be combined with more traditional methods used to determine the quality of a wellbore.

An example of a traditional method that may be used in conjunction with methods of the present disclosure include transmitting acoustic signals and receiving acoustic signals, performing evaluations on the acoustic signals, and making determinations from the received acoustic signals such that cement bond logs or semblance maps may be created. Evaluations performed by these traditional methods may identify amplitudes of transmitted and received acoustic signals and attenuation values associated with an acoustic wave traveling along a wellbore casing. Changes associated with the received acoustic signals may be associated with a quality of a portion of the wellbore, where increased levels of attenuation of transmitted signals may correspond to locations where little or no voids are located between the casing and an Earth formation. Outputs provided by the traditional methods may include a bond log map. Such traditional methods, however, can product outputs that have non-trivial patterns that are difficult to interpret. Because of this, traditional methods may not always adequately identify the quality of a wellbore cementing operation.

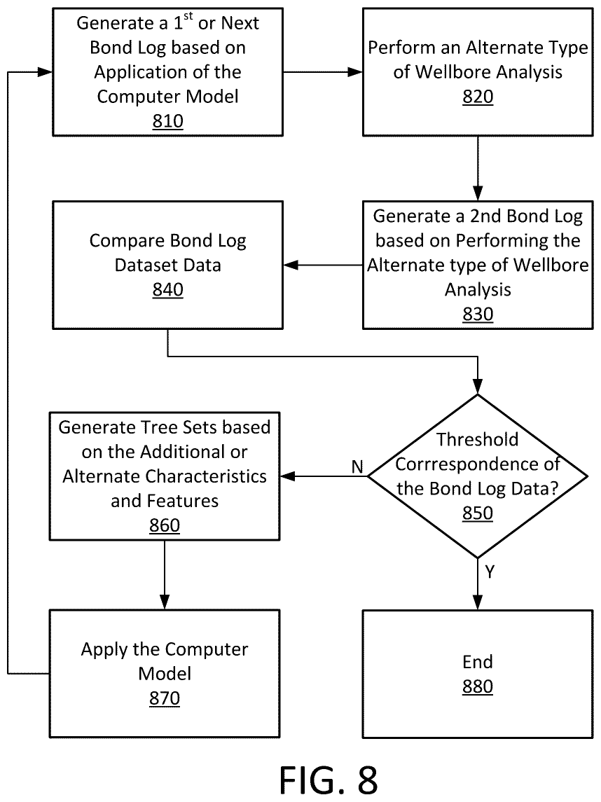

Despite the limitations associated with traditional methods of wellbore analysis, outputs from these traditional methods may be provided as inputs to a machine learning algorithm. This may include providing a bond log derived from a traditional method to a computer model that includes the Boolean tree discussed in respect to FIG. 5. The tree sets may be generated and applied as discussed in respect to steps 860 and 870 of FIG. 8 when the tree-based model of FIG. 5 is used to improve a wellbore bond log map. For example, the bond log data generated in step 830 of FIG. 8 may have been generated using a data from cement bond log generated by a traditional method.

FIG. 8 illustrates a set of actions that may be performed when a bond log generated based on using the computer model is validated. FIG. 8 begins with step 810 where a first or a next bond log is generated. Next in step 820, an alternative type (e.g. a more traditional method) of wellbore analysis may be performed, and a second bond log may be generated in step 830 based on the alternate type of wellbore analysis. The first or the next bond log may then be compared with the second bond log as part of the verification process in step 840. Each of the respective bond logs discussed in respect to FIG. 8 may include data that identifies locations that are completely cemented location of channels and potentially locations where channels are located. This bond logs may also include data that identifies how large particular channels are.

Determination step 850 may then identify whether the compared bond logs correspond to each other within a threshold level. This may include identifying whether the first bond log and the second bond log match each other with a 80% accuracy. In an instance when the first bond log indicates that a particular area of the wellbore is cemented well and when the second bond log also identifies that this area is cemented well, then those areas may correspond to each other by a factor of 100%. Determination step 850 may also include comparing to see whether the location and size of a channel identified by the first bond log matches a size and location of a channel included in the second bond log. For example, when the first bond log indicates that at a location of 500 feet into the wellbore that a channel has a width of 10 degrees, a thickness of 2 centimeters (cm), and a depth of 1 cm and the second bond log indicates at the 500 feet location that the channel has a width of 9.5 degrees, a thickness of 1.8 cm, and a depth of 1.03 cm, then equations may be performed to calculate whether the channel data from the two bond logs at the 500 foot level matches each other within the threshold correspondence level. Note that the values of channel depth of 10 degrees as compared to 9.5 degrees correspond to each other by about a 95% accuracy. Values of 2 cm versus 1.8 cm correspond to each other by about a 90% and values of 1 cm and 1.03 cm correspond to each other by about a 97% accuracy. When determination step 850 identifies that the compared bond log correspond to each other by the threshold correspondence level, program flow may end at step 880. Such an indication would validate that the bond logs generated using the current computer model matches bond logs generated using other techniques.

When determination step 850 identifies that the compared bond logs do not correspond to each other to the threshold level, program flow may move to step 860, where Boolean decision tree sets that use additional or alternate characteristics and features may be generated in step 860 and the computer model may be updated based on these additional or alternate characteristics and features. After the computer models has been updated the computer model may be applied in step 870. Step 870 may also identify whether the updated computer model still meets the threshold level of convergence as discussed in respect to step 760 of FIG. 7. After step 870, program flow may move back to step 810 where a next bond log is generated as the validation process of FIG. 8 continues.

This process of updating a computer model based on data from another type of analysis (e.g. a traditional analysis) may also include identifying a sensitivity associated with the computer model apparently making false detections. If it is found, for example, that a limit associated with a particular frequency is highly sensitive to a magnitude or attenuation included in a wellbore dataset, this may be an indication that the computer model could be improved by comparing results derived using information other types of wellbore analysis (e.g. the traditional analysis). Knowledge of this sensitivity for a set of characteristics and features may be used to bias the computer model such that it is more consistent with the traditional analysis.

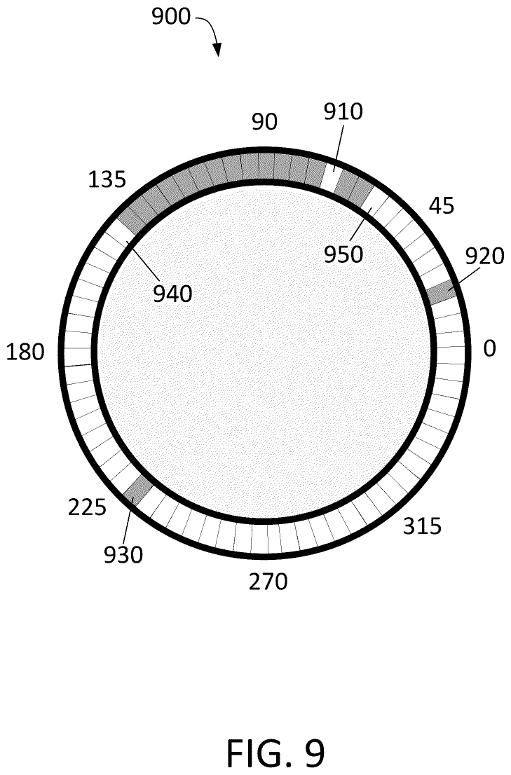

FIG. 9 illustrates an example set of data that shows areas of a wellbore cross-section that include areas fully filled with cement and areas where a channel appears to exist in the wellbore. The image 900 of the wellbore cross-section of FIG. 9 is circular in shape, areas of this cross-sectional image 900 are associated with a number of degrees of a circle. The numbers 0, 45, 90, 135, 180, 225, 270, and 315 included in FIG. 9 are degrees of this circle. Cross-sectional image 900 includes white colored zones and gray colored zones. Here, the white colored zones represent areas that appear to be filled with cement and the gray colored zones represent areas that appear to include a channel. Note that a channel has been identified near the 90-degree point of image 900 and that most of the other parts of the wellbore appear to not include a channel. Areas 910, 920, and 930 are small areas that may be associated with a false detection of either a channel or an area where a wellbore casing is securely cemented to an Earth formation. As such, area 910 may possibly be an area that includes a channel, rather than being securely cemented to the Earth formation—this means that area 910 may be a false securely cemented detection. Areas 920 and 930 may be areas where a channel has been falsely detected. Areas 910, 920, and 930 may be treated as areas where the computer model possibly generated erroneous results because these areas are surrounded by areas with an opposite detection. Since areas 940 and 950 are located at a boundary of areas that have a channel and areas that appear to be securely cemented. Because of this, detections associated with areas 940 and 950 may also be considered possible false detections.

In instances when possible false detections have been identified, the computer model may be updated to include alternative or additional trees. Here again, these alternative or additional trees may have been generated using updated characteristics and features. After the computer model is updated, it may be run again to see whether results associated with these possible false detections have changed. This process may also include identifying a sensitivity associated with the false detections. If it is found, for example, that a limit associated with a particular frequency is highly sensitive to a magnitude or attenuation included in a wellbore dataset, this may be an indication that the computer model could be improved by comparing results derived using information other types of wellbore analysis (e.g. a traditional analysis). Knowledge of this sensitivity for a set of characteristics and features may be used to bias the computer model such that it is more consistent with the traditional analysis.

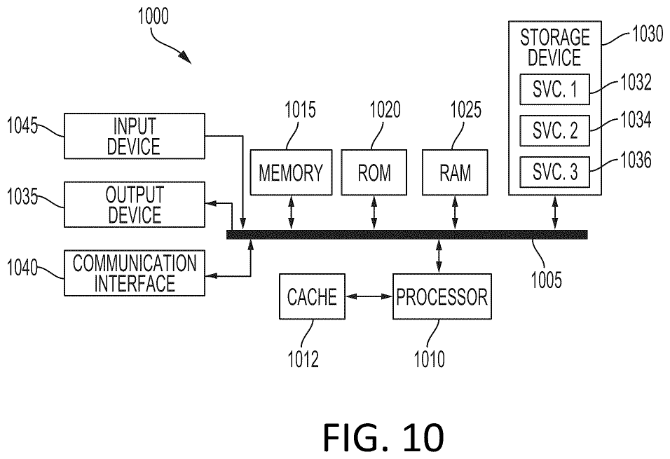

FIG. 10 illustrates an example computing device architecture 1000 which can be employed to perform various steps, methods, and techniques disclosed herein. Specifically, the computing device architecture can be integrated with the electromagnetic imager tools described herein. Further, the computing device can be configured to implement the techniques of controlling borehole image blending through machine learning described herein.

As noted above, FIG. 10 illustrates an example computing device architecture 1000 of a computing device which can implement the various technologies and techniques described herein. The components of the computing device architecture 1000 are shown in electrical communication with each other using a connection 1005, such as a bus. The example computing device architecture 1000 includes a processing unit (CPU or processor) 1010 and a computing device connection 1005 that couples various computing device components including the computing device memory 1015, such as read only memory (ROM) 1020 and random access memory (RAM) 1025, to the processor 1010.

The computing device architecture 1000 can include a cache of high-speed memory connected directly with, in close proximity to, or integrated as part of the processor 1010. The computing device architecture 1000 can copy data from the memory 1015 and/or the storage device 1030 to the cache 1012 for quick access by the processor 1010. In this way, the cache can provide a performance boost that avoids processor 1010 delays while waiting for data. These and other modules can control or be configured to control the processor 1010 to perform various actions. Other computing device memory 1015 may be available for use as well. The memory 1015 can include multiple different types of memory with different performance characteristics. The processor 1010 can include any general purpose processor and a hardware or software service, such as service 1 1032, service 2 1034, and service 3 1036 stored in storage device 1030, configured to control the processor 1010 as well as a special-purpose processor where software instructions are incorporated into the processor design. The processor 1010 may be a self-contained system, containing multiple cores or processors, a bus, memory controller, cache, etc. A multi-core processor may be symmetric or asymmetric.

To enable user interaction with the computing device architecture 1000, an input device 1045 can represent any number of input mechanisms, such as a microphone for speech, a touch-sensitive screen for gesture or graphical input, keyboard, mouse, motion input, speech and so forth. An output device 1035 can also be one or more of a number of output mechanisms known to those of skill in the art, such as a display, projector, television, speaker device, etc. In some instances, multimodal computing devices can enable a user to provide multiple types of input to communicate with the computing device architecture 1000. The communications interface 1040 can generally govern and manage the user input and computing device output. There is no restriction on operating on any particular hardware arrangement and therefore the basic features here may easily be substituted for improved hardware or firmware arrangements as they are developed.

Storage device 1030 is a non-volatile memory and can be a hard disk or other types of computer readable media which can store data that are accessible by a computer, such as magnetic cassettes, flash memory cards, solid state memory devices, digital versatile disks, cartridges, random access memories (RAMs) 1025, read only memory (ROM) 1020, and hybrids thereof. The storage device 1030 can include services 1032, 1034, 1036 for controlling the processor 1010. Other hardware or software modules are contemplated. The storage device 1030 can be connected to the computing device connection 1005. In one aspect, a hardware module that performs a particular function can include the software component stored in a computer-readable medium in connection with the necessary hardware components, such as the processor 1010, connection 1005, output device 1035, and so forth, to carry out the function.

For clarity of explanation, in some instances the present technology may be presented as including individual functional blocks including functional blocks comprising devices, device components, steps or routines in a method embodied in software, or combinations of hardware and software.

In some embodiments the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can include, for example, instructions and data which cause or otherwise configure a general purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc. Examples of computer-readable media that may be used to store instructions, information used, and/or information created during methods according to described examples include magnetic or optical disks, flash memory, USB devices provided with non-volatile memory, networked storage devices, and so on.

Devices implementing methods according to these disclosures can include hardware, firmware and/or software, and can take any of a variety of form factors. Typical examples of such form factors include laptops, smart phones, small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific embodiments thereof, but those skilled in the art will recognize that the application is not limited thereto. Thus, while illustrative embodiments of the application have been described in detail herein, it is to be understood that the disclosed concepts may be otherwise variously embodied and employed, and that the appended claims are intended to be construed to include such variations, except as limited by the prior art. Various features and aspects of the above-described subject matter may be used individually or jointly. Further, embodiments can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The various illustrative logical blocks, modules, circuits, and algorithm steps described in connection with the examples disclosed herein may be implemented as electronic hardware, computer software, firmware, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the method, algorithms, and/or operations described above. The computer-readable data storage medium may form part of a computer program product, which may include packaging materials.

The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

In the above description, terms such as “upper,” “upward,” “lower,” “downward,” “above,” “below,” “downhole,” “uphole,” “longitudinal,” “lateral,” and the like, as used herein, shall mean in relation to the bottom or furthest extent of the surrounding wellbore even though the wellbore or portions of it may be deviated or horizontal. Correspondingly, the transverse, axial, lateral, longitudinal, radial, etc., orientations shall mean orientations relative to the orientation of the wellbore or tool. Additionally, the illustrate embodiments are illustrated such that the orientation is such that the right-hand side is downhole compared to the left-hand side.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or another word that substantially modifies, such that the component need not be exact. For example, substantially cylindrical means that the object resembles a cylinder, but can have one or more deviations from a true cylinder.

The term “radially” means substantially in a direction along a radius of the object, or having a directional component in a direction along a radius of the object, even if the object is not exactly circular or cylindrical. The term “axially” means substantially along a direction of the axis of the object. If not specified, the term axially is such that it refers to the longer axis of the object.

Although a variety of information was used to explain aspects within the scope of the appended claims, no limitation of the claims should be implied based on particular features or arrangements, as one of ordinary skill would be able to derive a wide variety of implementations. Further and although some subject matter may have been described in language specific to structural features and/or method steps, it is to be understood that the subject matter defined in the appended claims is not necessarily limited to these described features or acts. Such functionality can be distributed differently or performed in components other than those identified herein. The described features and steps are disclosed as possible components of systems and methods within the scope of the appended claims.

Moreover, claim language reciting “at least one of” a set indicates that one member of the set or multiple members of the set satisfy the claim. For example, claim language reciting “at least one of A and B” means A, B, or A and B.

Statements of the disclosure include:

A method that includes the steps of identifying a set of Boolean operations to associate with a computer model. Each of respective Boolean operation of a set of operations may identify a characteristic that is associated with a feature of a set of wellbore features. This method may include generating the computer model that associates each respective Boolean operation with a respective preceding node that is links to a first respective following node when the respective Boolean operation has a True value and links to a second respective following node when the respective Boolean operation has a False value. This method may continue by accessing a second dataset associated with a second wellbore based on the first dataset and the second dataset each including the characteristic of the set of characteristics, and the first wellbore and the second wellbore each including the feature of the set of wellbore features. Other steps that may be included in the method may include applying the computer model to the second dataset to generate results to include in a bond map of the second wellbore and generating the bond map of the second wellbore from the results of applying the computer model to the second dataset.

Methods of the present disclosure may also include other steps such as identifying the set of characteristics associated with a first dataset that was acquired during operation of a wellbore tool at a first wellbore, and identifying a set of features of the first wellbore.

In certain instances, the set of characteristics may include one or more values associated with a frequency, a time value, a space value, or a time and a space value. Alternatively, or additionally, the set of wellbore features may include one or more of a type of casing, a type of ground material, a type of cement, a casing thickness, a casing inner diameter, a casing out diameter, a casing thickness, a channel thickness, an angle associated with an acoustic transmitter, a type of tubing, a tubing thickness, and a decentralization value of a transmitter from a location within the wellbore.

Other steps that may be included in methods of the present disclosure include one or more of modifying one or more characteristics of the first set of characteristics as part of the training of the computer model, applying the computer model to the first dataset after modifying the one or more characteristics, applying the computer model to the first dataset after the computer model is trained to generate a second set of results, generating a bond map of the first wellbore from the second set of results, and/or comparing the bond map of the first wellbore to data derived by applying an cement bonding measuring technique. Methods of the present disclosure may also include modifying the first dataset by performing a evaluations on data included in the first dataset or filtering data included in the first dataset. These evaluations may identify that certain data points should be removed from the first dataset, may identify data that should be added to the first dataset (by filling gaps in the dataset), or may identify that a second dataset should be merged with the first dataset. When wellbore data is collected, there may be issues that are inherent in a system used to acquire that data. For example, collected data may include or be contaminated with noise that may interfere with an analysis of the collected data. Processes of removing these unwanted noise signals may include identifying noise data and removing unwanted data associated with those unwanted noise signals. Unwanted noise can be generated when a wellbore tool bumps into/impacts a wellbore casing or other feature of the wellbore. Unwanted noise may also be generated when a temperature of the wellbore increases. Such unwanted noise may be removed by filtering the dataset. Filtering of the first dataset may include running a program that removes certain frequencies from the first dataset. For example, a set of equations may be performed that implements the function of a notch filter that removes only a limited band of unwanted frequencies from the first dataset. For example, when an emitted acoustic signal has a frequency of 50 KHz, frequencies above 200 KHz or below 10 Hz may be removed as being unwanted or irrelevant frequencies.

Methods of the present disclosure may be performed by a non-transitory computer-readable storage media, where a processor executes instructions out of a storage media such as a memory. Here again, the method may include any or all of the steps discussed above.

Apparatus consistent with the present disclosure may include a processor that executes instructions out of a memory when implementing methods of the present disclosure. This may include executing instructions to perform any or all of the steps of the method reviewed above.

What is claimed is:

1. A method comprising:
identifying a set of Boolean operations to associate with a computer model, wherein each respective Boolean operation of the set of Boolean operations identifies a characteristic of a set of characteristics and is associated with a feature of a set of wellbore features;
generating the computer model that associates each respective Boolean operation with a respective preceding node that is linked to a first respective following node when the respective Boolean operation has a True value and links to a second respective following node when the respective Boolean operation has a False value;
applying the computer model to a first dataset that is associated with a first wellbore when the computer model is trained;
accessing a second dataset associated with a second wellbore based on:
the first dataset and the second dataset each including the characteristic of the set of characteristics, and
the first wellbore and the second wellbore each including the feature of the set of wellbore features; and
applying the computer model to the second dataset to generate results to include in a bond map of the second wellbore; and
generating the bond map of the second wellbore from the results of applying the computer model to the second dataset.

2. The method of claim 1, further comprising:
identifying the set of characteristics associated with a first dataset that was acquired during operation of a wellbore tool at a first wellbore; and
identifying a set of features of the first wellbore.

3. The method of claim 1, wherein the set of characteristics includes one or more values associated with a frequency.

4. The method of claim 1, wherein the set of characteristics includes a time value and a space value.

5. The method of claim 1, wherein the set of wellbore features include one or more of a type of casing, a type of ground material, a type of cement, a casing thickness, a casing inner diameter, a casing out diameter, a casing thickness, a channel thickness, an angle associated with an acoustic transmitter, a type of tubing, a tubing thickness, and a decentralization value of a transmitter from a location within the wellbore.

6. The method of claim 1, further comprising:
modifying one or more characteristics of the first set of characteristics as part of the training of the computer model; and
applying the computer model to the first dataset after modifying the one or more characteristics.

7. The method of claim 6, further comprising:
applying the computer model to the first dataset after the computer model is trained to generate a second set of results;
generating a bond map of the first wellbore from the second set of results; and
comparing the bond map of the first wellbore to data derived by applying an cement bonding measuring technique.

8. The method of claim 1, further comprising:
performing an evaluation on data included in the first dataset; and
modifying the dataset based on the evaluation, wherein the modifying of the first dataset includes at least one of removing a first data point from or adding a second data point to the first dataset.

9. The method of claim 1, further comprising:
filtering data included in the first dataset to remove unwanted frequencies from the first dataset.

10. A non-transitory computer-readable storage medium having embodied thereon a program executable by a processor to perform a method comprising:
identifying a set of Boolean operations to associate with a computer model, wherein each respective Boolean operation of the set of Boolean operations identifies a characteristic of a set of characteristics and is associated with a feature of a set of wellbore features;
generating the computer model that associates each respective Boolean operation with a respective preceding node that is links to a first respective following node when the respective Boolean operation has a True value and links to a second respective following node when the respective Boolean operation has a False value;
applying the computer model to a first dataset that is associated with a first wellbore when the computer model is trained;
accessing a second dataset associated with a second wellbore based on:
the first dataset and the second dataset each including the characteristic of the set of characteristics, and
the first wellbore and the second wellbore each including the feature of the set of wellbore features; and
applying the computer model to the second dataset to generate results to include in a bond map of the second wellbore; and
generating the bond map of the second wellbore from the results of applying the computer model to the second dataset.

11. The non-transitory computer-readable storage medium of claim 10, further comprising:
identifying the set of characteristics associated with a first dataset that was acquired during operation of a wellbore tool at a first wellbore; and
identifying a set of features of the first wellbore.

12. The non-transitory computer-readable storage medium of claim 10, wherein the set of characteristics includes one or more values associated with a frequency.

13. The non-transitory computer-readable storage medium of claim 10, wherein the set of characteristics includes a time value and a space value.

14. The non-transitory computer-readable storage medium of claim 10, wherein the set of wellbore features include one or more of a type of casing, a type of ground material, a type of cement, a casing thickness, a casing inner diameter, a casing out diameter, a casing thickness, a channel thickness, an angle associated with an acoustic transmitter, a type of tubing, a tubing thickness, and a decentralization value of a transmitter from a location within the wellbore.

15. The non-transitory computer-readable storage medium of claim 10, the program further executable to:
modify one or more characteristics of the first set of characteristics as part of the training of the computer model; and
apply the computer model to the first dataset after modifying the one or more characteristics.

16. The non-transitory computer-readable storage medium of claim 15, the program further executable to:
apply the computer model to the first dataset after the computer model is trained to generate a second set of results;
generate a bond map of the first wellbore from the second set of results; and
compare the bond map of the first wellbore to data derived by applying an cement bonding measuring technique.

17. The non-transitory computer-readable storage medium of claim 10, the program further executable to:
perform an evaluation on data included in the first dataset; and
modifying the dataset based on the evaluation, wherein the modifying of the first dataset includes at least one of removing a first data point from or adding a second data point to the first dataset.

18. The non-transitory computer-readable storage medium of claim 10, the program further executable to:
filter data included in the first dataset to remove unwanted frequencies from the first dataset.

19. An apparatus comprising:
a memory; and
a processor that executes instructions out of the memory to:
identify a set of Boolean operations to associate with a computer model, wherein each respective Boolean operation of the set of Boolean operations identifies a characteristic of a set of characteristics and is associated with a feature of a set of wellbore features,
generate the computer model that associates each respective Boolean operation with a respective preceding node that is links to a first respective following node when the respective Boolean operation has a True value and links to a second respective following node when the respective Boolean operation has a False value;
applying the computer model to a first dataset that is associated with a first wellbore when the computer model is trained,
access a second dataset associated with a second wellbore based on:
the first dataset and the second dataset each including the characteristic of the set of characteristics, and
the first wellbore and the second wellbore each including the feature of the set of wellbore features, and
apply the computer model to the second dataset to generate results to include in a bond map of the second wellbore, and
generate the bond map of the second wellbore from the results of applying the computer model to the second dataset.

20. The apparatus of claim 19, wherein the processor also executes the instructions to:
identify the set of characteristics associated with a first dataset that was acquired during operation of a wellbore tool at a first wellbore, and
identify a set of features of the first wellbore.
